(19) United States
(12) Patent Application Publication
(10) Pub. No.: US 2015/0219697 A1
(43) Pub. Date: Aug. 6, 2015

(54) INTEGRATED CIRCUIT DETECTION CIRCUIT FOR A DIGITAL MULTI-LEVEL STRAP AND METHOD OF OPERATION THEREOF

(71) Applicant: Nvidia Corporation, Santa Clara, CA (US)

(72) Inventors: Victor Chen, Santa Clara, CA (US); Jesse Max Guss, Santa Clara, CA (US); Craig Ross, Santa Clara, CA (US); Kevin Wong, Santa Clara, CA (US); Jason Kwok-san Lee, Santa Clara, CA (US)

(73) Assignee: Nvidia Corporation, Santa Clara, CA (US)

(21) Appl. No.: 14/173,241

(22) Filed: Feb. 5, 2014

(51) Int. Cl. G01R 19/165; G06T 1/20

(52) U.S. Cl. CPC G01R 19/165; G06T 1/20; G09G 2370/00

(57) ABSTRACT

An integrated circuit (IC) based detection circuit for determining a strap value and a method of detecting a digital strap value. In one embodiment, the detection circuit includes: (1) a first receiver including transistors having first electrical characteristics that define a first threshold for the first receiver, the first receiver operable to generate a first binary digit based on an input signal and the first threshold and (2) a second receiver including transistors having second electrical characteristics that differ from the first electrical characteristics and define a second threshold for the second receiver that is lower than the first threshold, the second receiver operable to generate a second binary digit based on the input signal and the second threshold, the first and second binary digits indicating whether the strap value lies above the first threshold, between the first and second thresholds or below the second threshold.

### TECHNICAL FIELD

This application is directed, in general, to integrated circuits (ICs) and, more specifically, to an IC-based detection circuit for a digital multi-level strap and a method of using the same.

### BACKGROUND

It is often advantageous for an IC mounted on a printed circuit board (PCB) in a given platform to receive information specific to the platform. For example, if an IC includes a fan controller, it may be beneficial to select an initial duty cycle for the fan controller based upon the specific fan they employed in a particular environment. Another example is selecting the best electrical settings to optimize Peripheral Connect Interface Express (PCIE) drive strength, sometimes required even before PCIE has become trained. In such cases, a strap is used to provide the information to the IC.

The simplest strap implementation, a binary strap, consists of a detection circuit and a PCB resistor. The PCB resistor can be either pulled up to an upper rail (i.e. Vdd), or pulled down to a lower rail (i.e. ground). This arrangement yields only one binary digit per pin: either a one or a zero.

### SUMMARY

One aspect provides an IC based detection circuit for determining a strap value and a method of detecting a digital strap value. In one embodiment, the detection circuit includes: (1) a first receiver including transistors having first electrical characteristics that define a first threshold for the first receiver, the first receiver operable to generate a first binary digit based on an input signal and the first threshold and (2) a second receiver including transistors having second electrical characteristics that differ from the first electrical characteristics and define a second threshold for the second receiver that is lower than the first threshold, the second receiver operable to generate a second binary digit based on the input signal and the second threshold, the first and second binary digits indicating whether the strap value lies above the first threshold, between the first and second thresholds or below the second threshold.

Another aspect provides a method of detecting a digital strap value. In one embodiment, the method includes: (1) receiving an input signal in a first receiver and a second receiver, (2) generating a first binary digit based on the input signal and a first threshold determined by first electrical characteristics of transistors in the first receiver, (3) generating a second binary digit based on the input signal and a second threshold determined by second electrical characteristics of transistors in the second receiver, the second electrical characteristics differing from the first electrical characteristics and the first threshold being higher than the second threshold and (4) employing the first and second binary digits to determine whether the strap value lies above the first threshold, between the first and second thresholds or below the second threshold.

Yet another aspect provides a graphics processing unit (GPU). In one embodiment, the GPU includes: (1) graphics processing circuitry configured to operate based at least in part on a strap value determined by strap circuitry on a circuit board to which the graphics processing circuitry is coupled, (2) a first receiver coupled to the graphics processing circuitry and including transistors having first electrical characteristics that define a first threshold for the first receiver, the first receiver operable to generate a first binary digit based on an input signal and the first threshold and (3) a second receiver coupled to the graphics processing circuitry and including transistors having second electrical characteristics that differ from the first electrical characteristics and define a second threshold for the second receiver that is lower than the first threshold, the second receiver operable to generate a second binary digit based on the input signal and the second threshold, the first and second binary digits indicating whether the strap value lies above the first threshold, between the first and second thresholds or below the second threshold, the graphics processing circuitry operable to receive the first and second binary digits.

### BRIEF DESCRIPTION

Reference is now made to the following descriptions taken in conjunction with the accompanying drawings, in which:

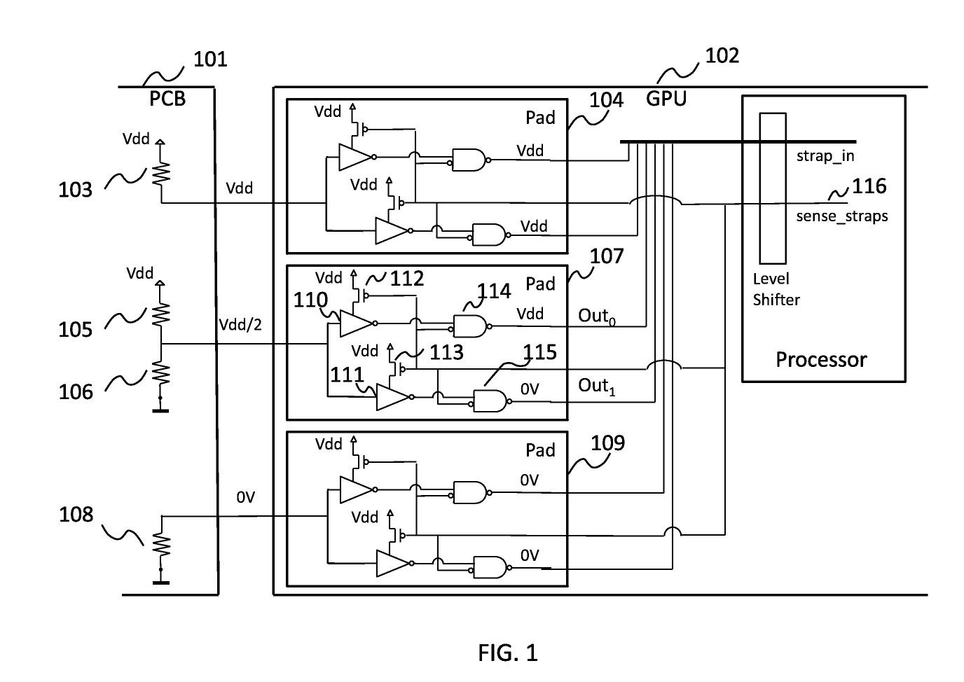

FIG. 1 is an exemplary illustration of three ternary straps configured for three different voltage levels;

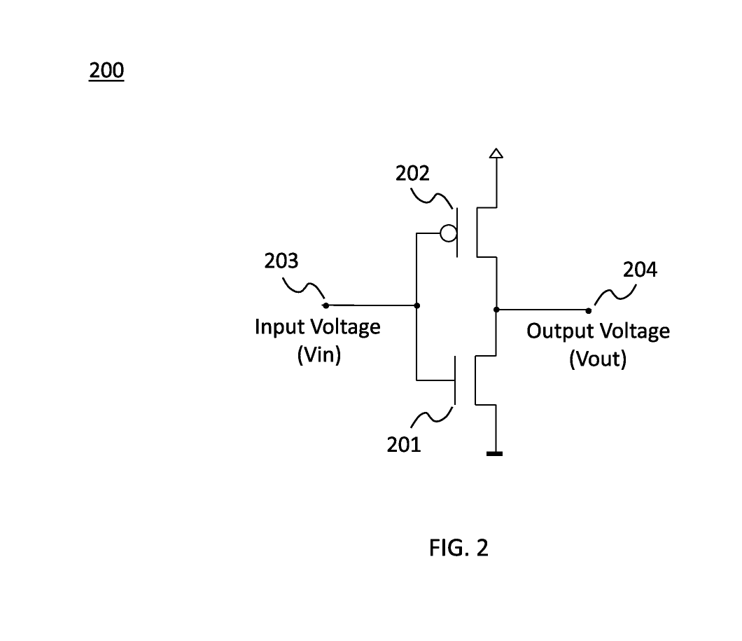

FIG. 2 is a schematic diagram of an inverter;

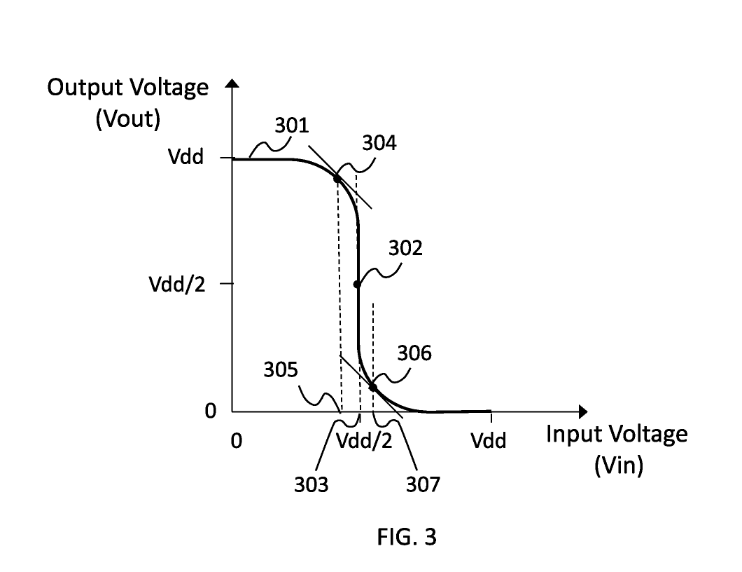

FIG. 3 is an illustration of the input-output characteristics of an inverter;

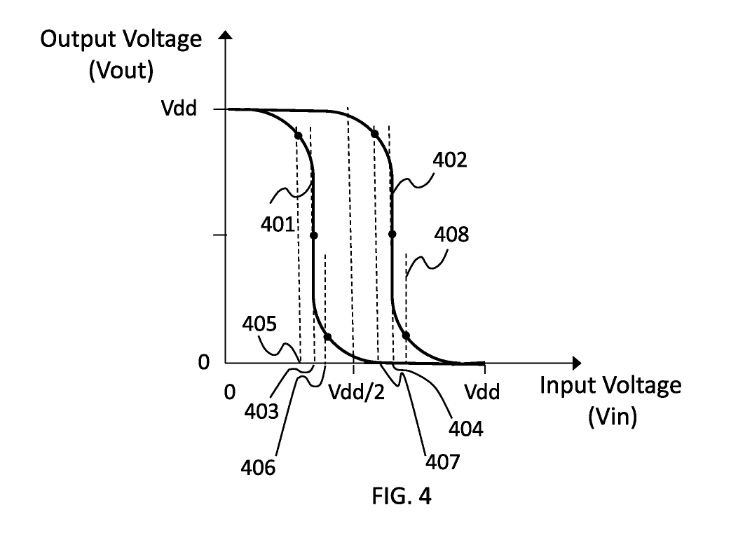

FIG. 4 is an illustration of the input-output characteristics of two inverters with differing threshold voltages; and

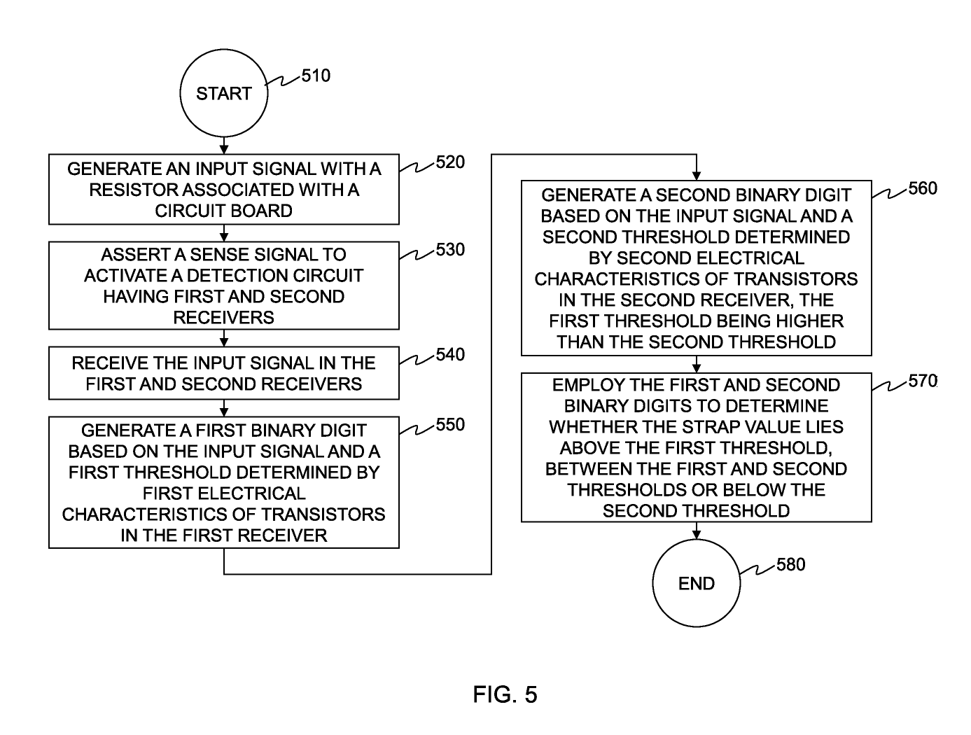

FIG. 5 is a flow diagram of one embodiment of a method of detecting a digital strap value.

### DETAILED DESCRIPTION

It is realized herein that with binary straps, many pins are needed to implement the relatively large quantity of information typical applications desire. It would be beneficial to reduce the number of pins required. Enabling each pin to convey more than one binary digit is therefore desirable. A multi-level strap provides a way to provide more information per pin. However, the detection circuit in the IC must detect voltage levels other than 0 and Vdd.

It is further realized herein that, while multi-level straps hold promise, the circuitry required to detect the value of a given strap tends to be complex. It is realized, however, that the potential exists to make the detection circuit simpler. More specifically, it is realized herein that electrical characteristics that are intrinsic to the transistors in a detection circuit can be varied to accommodate multi-level straps.

Accordingly, introduced herein are various embodiments of a detection circuit and method of detecting digital strap values. In one embodiment, for an N-value strap, N−1 transistor-based (e.g., complementary metal oxide semiconductor field-effect transistor, or CMOS) receivers are designed to have threshold values intermediate between N strap voltage levels. For each strap voltage value, each receiver produces a low or high output depending on its threshold. Together, the receivers produce a unique combination of N−1 low or high output signals, which is then used to infer the strap value. The use of such receivers results in lower circuit area, lower power consumption, and better reliability than methods requiring more complex circuitry. In one embodiment, the receivers are inverters.

Whereas a binary strap provides N=2 values, a ternary strap provides N=3 values, a quaternary strap provides N=4 values, and so on. Introduced herein is a detection circuit including N−1 receivers is used to detect the voltage level. Furthermore, the input thresholds of the receivers are different such that each intended voltage level input to the detection circuit produces a different set of receiver outputs.

FIG. 1 is an illustration of an embodiment of three ternary straps configured for three different voltage levels, implemented on a board 101 and with an IC that happens to be a GPU 102. Those skilled in the pertinent art will understand that straps of these or other configurations may be employed with any IC, and not just a GPU.

In the first strap, having a pull-up resistor 103 and a pad 104, the pull-up resistor 103 is connected to Vdd, providing a voltage level of Vdd to the pad 104. The second strap has a pull-up resistor 105, a pull-down resistor 106 with the same resistance value as the pull-up resistor 105, and a pad 107. The pull-up resistor 105 and the pull-down resist 106 are connected to Vdd and ground, respectively, providing a voltage level of Vdd/2 to the pad 107. In the third strap, having a pull-down resistor 108 and a pad 109, the pull-down resistor 108 is connected to ground, providing a voltage level of zero to the pad 109. In this embodiment, the pads 104, 107, 109 are identical.

The pad 107 contains receivers 110, 111, power gates 112, 113, and logic circuits 114, 115. In this embodiment, the receivers 110, 111 are inverters. A sense_straps signal 116 enables strap detection by powering the receivers 110, 111 through the power gates 112, 113. The sense_straps signal 116 also gates the logic circuits 114, 115 to produce binary digits Out₀ and Out₁ at the output of the pad 107.

The receiver 110, designed such that its input threshold is lower than Vdd/2, sees an input voltage of Vdd/2 as a logical high input and produces a logical low output of 0V, leading to a logical high signal of Vdd for Out₀ at the output of the pad 107. By contrast, the receiver 111, designed such that its input threshold is higher than Vdd/2, sees the same input voltage as a logical low input and produces a logical high output of Vdd, leading to a logical low signal of 0V for Out₁ at the output of the pad 107.

In the pad 104, the input voltage of Vdd is higher than the input thresholds of both receivers, producing two high signals of Vdd at the output. In the pad 109, the input voltage of 0V is lower than the input thresholds of both receivers, producing two low signals of 0V at the output. The outputs of the pads 104, 107, 109 are shown in Table 1, below. Table 1 illustrates how each of the three input voltages of a ternary strap can be detected with a unique pair of binary digits Out₁ and Out₀.

TABLE 1
Outputs of the pads 104, 107, and 109 of FIG. 1.

| Input Voltage (V) | Out₁ | Out₀ |
|---|---|---|
| 0 | 0 | 0 |
| Vdd/2 | 0 | 1 |
| Vdd | 1 | 1 |

FIG. 2 is an illustration of a CMOS inverter 200, having an NMOS transistor 201 and a PMOS transistor 202. An input voltage is applied to an input port 203, producing an output voltage at an output port 204. For the NMOS transistor 201, a kₙ value is commonly defined as kₙ=μₙC_{ox,n}Wₙ/Lₙ, where μₙ is the mobility, C_{ox,n} is the oxide capacitor, and Wₙ and Lₙ are gate width and length, respectively. For the PMOS transistor 202, a kₙ value is commonly defined as kₚ=μₚC_{ox,p}Wₚ/Lₚ, where the symbols have the corresponding meanings for the PMOS transistor 202. The ratio k_{R}=kₙ/kₚ is a measure of the relative strengths of the NMOS and PMOS transistors 201, 202.

FIG. 3 is an illustration of the input-output characteristics of an inverter. An input-output curve 301 traces the relationship between the input and output voltages. At a point 302, input and output voltages are equal. It is customary to define the input voltage value corresponding to this point as an inverter threshold voltage (Vₜₕ) value 303. In the present context, however, it is more convenient to define the inverter threshold voltage to be the input value corresponding to the vertical portion of the input-output curve 301. For the input-output curve 301, the threshold value under the latter definition is the same value 303. It is also customary to define two additional input voltages. The slope of the input-output curve 301 is −1 at the points 304, 306. The input voltage corresponding to the point 304 is defined as the input-low voltage 305 (V_{IL}), whereas that corresponding to the point 306 is defined as the input-high voltage 307 (V_{IH}).

The position of the input-output curve 301 along the input-voltage axis and the values of the threshold voltage value 303, V_{IL} 305, and V_{IH} 307 are functions of various parameters of the NMOS transistor 201 and PMOS transistor 202, notably their transistors threshold voltages and their relative strengths, reflected in the k_{R} ratio. A high k_{R} ratio, indicating a relatively stronger NMOS, may be achieved by employing a larger NMOS Wₙ/Lₙ compared to the PMOS Wₚ/Lₚ, thereby shifting the input-output curve 301 left and resulting in lower values for the threshold voltage 303, V_{IL} 305, and V_{IH} 307. By contrast, a low k_{R} ratio, indicating a relatively stronger PMOS, may be achieved by employing a smaller NMOS Wₙ/Lₙ compared to the PMOS Wₚ/Lₚ, shifting the input-output curve 301 right and resulting in higher values for the threshold voltage value 303, V_{IL} 305, and V_{IH} 307. As k_{R} approaches infinity or zero, the input-output curve 301 shift approaches a maximum amount limited by the transistor threshold voltages of the NMOS transistor 201 and the PMOS transistor 202.

FIG. 4 is an illustration of the input-output characteristics of two inverters with different threshold voltages. An input-output curve 401 has an inverter threshold voltage 403 lower than Vdd/2, while the input-output curve 402 has an inverter threshold voltage 404 higher than Vdd/2. Using an inverter with the inverter threshold voltage 403 as the receiver 110 of FIG. 1 and an inverter with the inverter threshold voltage 404 as the receiver 111 of FIG. 1 will result in the detection of strap signals as shown in Table 1.

For a ternary strap with Vdd=3.3V and NMOS and PMOS transistor threshold values of 0.7V and −0.7V, respectively, k_{R}>1 results in an inverter threshold voltage lower than Vdd/2, and k_{R}<1 results in an inverter threshold voltage higher than Vdd/2. In one embodiment having a more reliable operation, the inverters such that not only the inverter threshold 401, but also V_{IL} 405 and V_{IH} 406 are safely lower than Vdd/2. Likewise, the inverter threshold 402, but also V_{IL} 407 and V_{IH} 408 are safely higher than Vdd/2. In an inverter, V_{IH} is necessarily higher than V_{IL}. In addition, care should be taken in designing the inverters to provide adequate margin over variations in the manufacturing process, supply voltage, and temperature. In one embodiment, the value of k_{R} is raised sufficiently above one for the inverter with the lower threshold and sufficiently below one for the inverter with the higher threshold, to meet the margins desired.

For a quaternary strap, resistors on the printed circuit board are used to produce four voltage values, zero, Vdd, and two intermediate voltage values V₁ and V₂ such that 0<V₁<V₂<Vdd. Three receivers are then employed in the pad, with threshold values between zero and V₁, between V₁ and V₂, and between V₂ and Vdd, respectively. For maximum separation between voltages, the two intermediate values may be selected as V₁=Vdd/3 and V₂=2Vdd/3. However, if the receivers are inverters and NMOS and PMOS transistor threshold voltages are relatively high, it may be challenging to design an inverter with an inverter threshold voltage safely lower than Vdd/3 or higher than 2Vdd/3. In such cases, it is preferable to select the two intermediate voltages closer to Vdd/2. For a given receiver design, those skilled in the pertinent art are able to design the proper combination of board voltage values and receiver thresholds without undue experimentation.

In the embodiment above, weak pull-up and pull-down resistors are placed on the circuit board. In an alternative embodiment, pull-down resistors are implemented in the processor itself. This embodiment saves cost and area on the circuit board. It can also reduce static current, by gating off power to the pull-down resistor when the strap is not being sensed. Various embodiments have one or more of the following advantages. In comparison to binary straps, the detection circuit introduced herein results in reduced pin count. In particular, to communicate S settings with binary straps, P binary straps are needed where 2^{P}=S. For example, for eight settings, three binary strap pins are required. With ternary straps, however, S settings may be communicated with P straps where 3^{P}=S. For example, nine settings may be communicated with two pins. More generally, P N-value straps can communicate S settings, where N^{P}=S. Furthermore, the present invention permits fast sensing of the strap value, so long as the power supply for the external termination (weak pull-up) and the receiver pad are stable. A simple counter is all that is required in order to ensure that the voltage is stable.

In addition, by employing receivers, the present invention reduces the chip area required for the detection circuitry, as well as power consumption, versus other solutions that require complex circuits such as current sources, filters, and analog-to-digital converters (ADCs).

FIG. 5 is a flow diagram of one embodiment of a method of detecting a digital strap value. In one embodiment, the method is carried out in an IC coupled to a PCB which presents an environment to the IC to which the IC should adapt. The digital strap value provides at least some of the information allowing the IC to adapt to the environment.

The method begins in a start step 510. In a step 520, an input signal is generated on a PCB, which may be carried out by means of one or more resistors. In a step 530, a sense signal is asserted to activate a receiver having first and second receivers. In a step 540, the input signal is received in the first and second receivers. In a step 550, a first binary digit is generated based on the input signal and a first threshold determined by first electrical characteristics of transistors in the first receiver. In a step 560, a second binary digit is generated based on the input signal and a second threshold determined by second electrical characteristics of transistors in the second receiver. In the embodiment of FIG. 5, the steps 550, 560 occur concurrently. The first threshold is higher than the second threshold.

In a step 570, the first and second binary digits are employed to determine whether the strap value lies above the first threshold, between the first and second thresholds or below the second threshold. In one embodiment, the step 570 is carried out by providing the first and second binary digits to a processor located on a common substrate with the first and second receivers and installed on the circuit board. The method ends in an end step 580.

Those skilled in the art to which this application relates will appreciate that other and further additions, deletions, substitutions and modifications may be made to the described embodiments.

What is claimed is:

1. An integrated circuit based detection circuit for determining a strap value, comprising:
a first receiver including transistors having first electrical characteristics that define a first threshold for said first receiver, said first receiver operable to generate a first binary digit based on an input signal and said first threshold; and
a second receiver including transistors having second electrical characteristics that differ from said first electrical characteristics and define a second threshold for said second receiver that is lower than said first threshold, said second receiver operable to generate a second binary digit based on said input signal and said second threshold, said first and second binary digits indicating whether said strap value lies above said first threshold, between said first and second thresholds or below said second threshold.

2. The detection circuit as recited in claim 1 wherein said first threshold defines a first range lying between an upper rail value and said first threshold, said second threshold defines a second range lying between said second threshold and a lower rail value, and said first and second thresholds define a third range lying between said first and second thresholds.

3. The detection circuit as recited in claim 1 wherein said first and second thresholds are voltage thresholds.

4. The detection circuit as recited in claim 1 wherein said transistors are complementary metal-oxide semiconductor field-effect transistors.

5. The detection circuit as recited in claim 1 wherein said first receiver comprises a first inverter and said second receiver comprises a second inverter.

6. The detection circuit as recited in claim 1 further comprising sense circuitry coupled to said first and second receivers and operable to activate said first and second receivers to provide said first and second binary digits when a sense signal is asserted.

7. The detection circuit as recited in claim 6 wherein said detection circuit is part of a processor configured to be installed on a printed circuit board, and a resistor associated with said printed circuit board is operable to generate said input signal.

8. A method of detecting a digital strap value, comprising:
receiving an input signal in a first receiver and a second receiver;
generating a first binary digit based on said input signal and a first threshold determined by first electrical characteristics of transistors in said first receiver;
generating a second binary digit based on said input signal and a second threshold determined by second electrical characteristics of transistors in said second receiver, said second electrical characteristics differing from said first electrical characteristics, said first threshold being higher than said second threshold; and
employing said first and second binary digits to determine whether said strap value lies above said first threshold, between said first and second thresholds or below said second threshold.

9. The method as recited in claim 8 wherein said first threshold defines a first range lying between an upper rail value and said first threshold, said second threshold defines a second range lying between said second threshold and a lower rail value, and said first and second thresholds define a third range lying between said first and second thresholds.

10. The method as recited in claim 8 wherein said first and second thresholds are voltage thresholds.

11. The method as recited in claim 8 wherein said transistors are complementary metal-oxide semiconductor field-effect transistors.

12. The method as recited in claim 8 wherein said first receiver comprises a first inverter and said second receiver comprises a second inverter.

13. The method as recited in claim 8 further comprising carrying out said generating by asserting a sense signal.

14. The method as recited in claim 13 further comprising providing said first and second binary digits to a processor located on a common substrate with said first and second receivers and configured to be installed on a printed circuit board; and
generating said input signal with at least one resistor associated with said printed circuit board.

15. A graphics processing unit, comprising:
graphics processing circuitry configured to operate based at least in part on a strap value determined by strap circuitry on a printed circuit board to which said graphics processing circuitry is coupled;
a first receiver coupled to said graphics processing circuitry and including transistors having first electrical characteristics that define a first threshold for said first receiver, said first receiver operable to generate a first binary digit based on an input signal and said first threshold; and
a second receiver coupled to said graphics processing circuitry and including transistors having second electrical characteristics that differ from said first electrical characteristics and define a second threshold for said second receiver that is lower than said first threshold, said second receiver operable to generate a second binary digit based on said input signal and said second threshold, said first and second binary digits indicating whether said strap value lies above said first threshold, between said first and second thresholds or below said second threshold, said graphics processing circuitry operable to receive said first and second binary digits.

16. The graphics processing unit as recited in claim 15 wherein said first threshold defines a first range lying between an upper rail value and said first threshold, said second threshold defines a second range lying between said second threshold and a lower rail value, and said first and second thresholds define a third range lying between said first and second thresholds.

17. The graphics processing unit as recited in claim 15 wherein said first and second thresholds are voltage thresholds.

18. The graphics processing unit as recited in claim 15 wherein said transistors are complementary metal-oxide semiconductor field-effect transistors.

19. The graphics processing unit as recited in claim 15 wherein said first receiver comprises a first inverter and said second receiver comprises a second inverter.

20. The graphics processing unit as recited in claim 15 further comprising sense circuitry coupled to said first and second receivers and operable to activate said first and second receivers to provide said first and second binary digits when a sense signal is asserted.
